(19) United States
(12) Patent Application Publication
(10) Pub. No.: US 2019/0130971 A1
(43) Pub. Date: May 2, 2019

(54) WRITE-TIME PREVENTION OF DATA RETENTION FAILURES FOR NON-VOLATILE MEMORY

(71) Applicant: SanDisk Technologies LLC, Plano, TX (US)

(72) Inventor: Bijesh Rajamohanan, Milpitas, CA (US)

(73) Assignee: SanDisk Technologies LLC, Plano, TX (US)

(21) Appl. No.: 15/800,037

(22) Filed: Oct. 31, 2017

(51) Int. Cl. G11C 13/00

(52) U.S. Cl. CPC G11C 13/0064; G11C 13/0069; G11C 13/0004

(57) ABSTRACT

Apparatuses, systems, and methods are disclosed for write-time prevention of data retention failures for non-volatile memory. An apparatus may include an array of non-volatile memory cells and a controller. A controller may be configured to perform a write operation for at least one cell. A controller may be configured to identify, during a write operation, one or more cells for which a characteristic of the one or more identified cells is associated with data retention failure. A controller may be configured to modify a write operation for one or more identified cells.

### TECHNICAL FIELD

The present disclosure, in various embodiments, relates to non-volatile memory and more particularly relates to write-time prevention of data retention failures for non-volatile memory.

### BACKGROUND

Various types of memory devices store data in two-dimensional or three-dimensional arrays of memory cells. Physical and/or electrical properties of the memory cells may be altered to write data, and sensed to read data. However, a cell may fail to retain data, resulting in read errors, if unintended changes to the data-encoding physical or electrical property of a cell occur. For example, data retention errors may be related to charge leakage in Flash memory, room-temperature phase changes for phase change memory, relaxation of conductive structures (e.g., filaments) for resistive memory, or the like.

### SUMMARY

Apparatuses are presented for write-time prevention of data retention failures for non-volatile memory. An apparatus, in one embodiment, includes an array of non-volatile memory cells and a controller. A controller, in one embodiment, is configured to perform a write operation for at least one cell. In a certain embodiment, a controller is configured to identify, during a write operation, one or more cells for which a characteristic of the one or more identified cells is associated with data retention failure. In a further embodiment, a controller is configured to modify a write operation for one or more identified cells.

Methods are presented for write-time prevention of data retention failures for non-volatile memory. In one embodiment, a method includes beginning a write operation for a cell of a non-volatile memory array. In a certain embodiment, a method includes determining, during a write operation, whether a write loop count is out of bounds. In a further embodiment, a method includes modifying a write operation in response to determining that a write loop count is out of bounds.

An apparatus, in another embodiment, includes means for performing a write operation for at least one cell of a non-volatile memory array. In a certain embodiment, an apparatus includes means for identifying, during a write operation, one or more cells for which a write loop count violates a threshold. In a further embodiment, an apparatus includes means for modifying one or more verify thresholds for identified cells during a write operation.

### BRIEF DESCRIPTION OF THE DRAWINGS

A more particular description is included below with reference to specific embodiments illustrated in the appended drawings. Understanding that these drawings depict only certain embodiments of the disclosure and are not therefore to be considered to be limiting of its scope, the disclosure is described and explained with additional specificity and detail through the use of the accompanying drawings, in which:

FIG. 1 is a schematic block diagram illustrating one embodiment of a system comprising non-volatile memory elements;

FIG. 2 is a schematic block diagram illustrating another embodiment of a system comprising non-volatile memory elements;

FIG. 3 is a graph illustrating cell currents for an array of non-volatile memory cells;

FIG. 4 is a graph illustrating a write loop count for multiple write operations for a non-volatile memory cell;

FIG. 5 is a schematic block diagram illustrating one embodiment of a write-time adjustment component;

FIG. 6 is a schematic block diagram illustrating another embodiment of a write-time adjustment component;

FIG. 7 is a schematic flow chart diagram illustrating one embodiment of a method for write-time prevention of data retention failures for non-volatile memory; and

FIG. 8 is a schematic flow chart diagram illustrating another embodiment of a method for write-time prevention of data retention failures for non-volatile memory.

### DETAILED DESCRIPTION

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like.

Modules may also be implemented at least partially in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may include a single instruction, or many instructions, and may even be distributed over several different code segments, among different programs, across several memory devices, or the like. Where a module or portions of a module are implemented in software, the software portions may be stored on one or more computer readable and/or executable storage media. Any combination of one or more computer readable storage media may be utilized. A computer readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

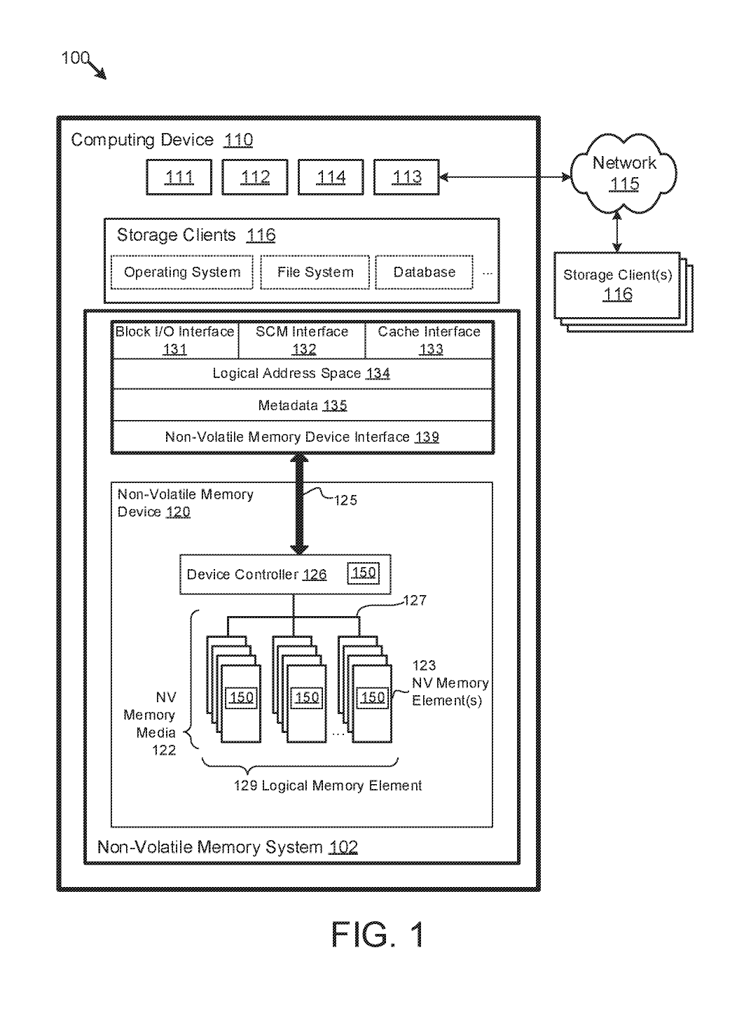

FIG. 1 is a block diagram of one embodiment of a system 100 comprising one or more write-time adjustment components 150 for a non-volatile memory device 120. Write-time adjustment components 150 may be part of one or more non-volatile memory elements 123, a device controller 126 external to the non-volatile memory elements 123, a device driver, or the like. Write-time adjustment components 150 may be part of a non-volatile memory system 102 of a computing device 110, which may comprise a processor 111, volatile memory 112, and a communication interface 113. The processor 111 may comprise one or more central processing units, one or more general-purpose processors, one or more application-specific processors, one or more virtual processors (e.g., the computing device 110 may be a virtual machine operating within a host), one or more processor cores, or the like. The communication interface 113 may comprise one or more network interfaces configured to communicatively couple the computing device 110 and/or device controller 126 to a communication network 115, such as an Internet Protocol (IP) network, a Storage Area Network (SAN), wireless network, wired network, or the like.

The non-volatile memory device 120, in various embodiments, may be disposed in one or more different locations relative to the computing device 110. In one embodiment, the non-volatile memory device 120 comprises one or more non-volatile memory elements 123, such as semiconductor chips or packages or other integrated circuit devices disposed on one or more printed circuit boards, storage housings, and/or other mechanical and/or electrical support structures. For example, the non-volatile memory device 120 may comprise one or more direct inline memory module (DIMM) cards, one or more expansion cards and/or daughter cards, a solid-state-drive (SSD) or other hard drive device, and/or may have another memory and/or storage form factor. The non-volatile memory device 120 may be integrated with and/or mounted on a motherboard of the computing device 110, installed in a port and/or slot of the computing device 110, installed on a different computing device 110 and/or a dedicated storage appliance on the network 115, in communication with the computing device 110 over an external bus (e.g., an external hard drive), or the like.

The non-volatile memory device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the non-volatile memory device 120 may be disposed on a peripheral bus of the computing device 110, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the non-volatile memory device 120 may be disposed on a data network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The computing device 110 may further comprise a non-transitory, computer readable storage medium 114. The computer readable storage medium 114 may comprise executable instructions configured to cause the computing device 110 (e.g., processor 111) to perform steps of one or more of the methods disclosed herein.

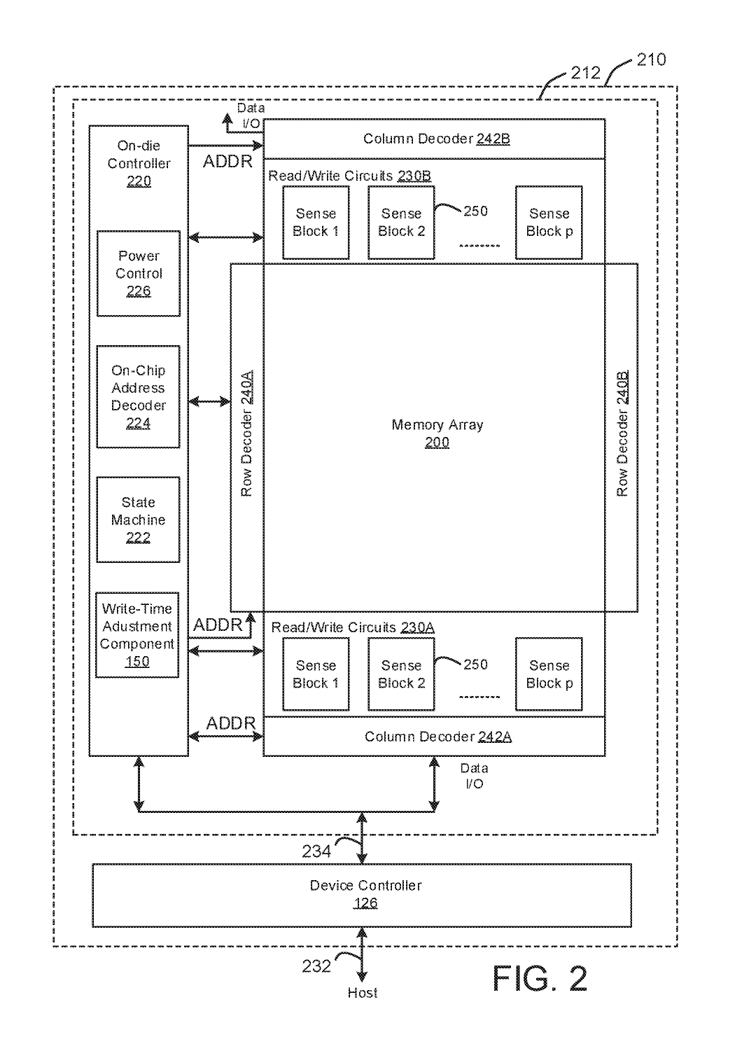

The non-volatile memory system 102, in the depicted embodiment, includes one or more write-time adjustment components 150. A write-time adjustment component 150, in one embodiment, may be configured to perform a write operation for one or more non-volatile memory cells, identify one or more cells, during the write operation, with a characteristic associated with data retention failure, and modify the write operation for the identified cells. In certain types of memory, a data retention failure may be predicted at write time, based on certain characteristics. By identifying cells with such characteristics, a write-time adjustment component 150 may predict where a data failure is likely. In turn, modifying the write operation for the identified cells may mitigate or prevent a predicted data retention failure. Write-time adjustment components 150 are described in greater detail below with regard to FIGS. 2-8.

In one embodiment, a write-time adjustment component 150 may include logic hardware of one or more non-volatile memory devices 120, such as a device controller 126, a non-volatile memory element 123, other programmable logic, firmware for a for a non-volatile memory element 123, microcode for execution by a non-volatile memory element 123, or the like. In another embodiment, a write-time adjustment component 150 may include executable software code, stored on a computer readable storage medium for execution by logic hardware of a non-volatile memory element 123. In a further embodiment, a write-time adjustment component 150 may include a combination of both executable software code and logic hardware.

In one embodiment, the non-volatile memory device 120 is configured to receive storage requests from a device driver or other executable application via buses 125, 127, a device controller 126, or the like. The non-volatile memory device 120 may be further configured to transfer data to/from a device driver and/or storage clients 116 via the bus 125. Accordingly, the non-volatile memory device 120, in some embodiments, may comprise and/or be in communication with one or more direct memory access (DMA) modules, remote DMA modules, bus controllers, bridges, buffers, and so on to facilitate the transfer of storage requests and associated data. In another embodiment, the non-volatile memory device 120 may receive storage requests as an API call from a storage client 116, as an IO-CTL command, or the like.

According to various embodiments, a device controller 126 may manage one or more non-volatile memory devices 120 and/or non-volatile memory elements 123. The non-volatile memory device(s) 120 may comprise recording, memory, and/or storage devices, such as solid-state storage device(s) and/or semiconductor storage device(s) that are arranged and/or partitioned into a plurality of addressable media storage locations. As used herein, a media storage location refers to any physical unit of memory (e.g., any quantity of physical storage media on a non-volatile memory device 120). Memory units may include, but are not limited to: pages, memory divisions, blocks, sectors, collections or sets of physical storage locations (e.g., logical pages, logical blocks), or the like.

A device driver and/or the device controller 126, in certain embodiments, may present a logical address space 134 to the storage clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the non-volatile memory device 120 may maintain metadata 135, such as a logical to physical address mapping structure, to map logical addresses of the logical address space 134 to media storage locations on the non-volatile memory device(s) 120. A device driver may be configured to provide storage services to one or more storage clients 116. The storage clients 116 may include local storage clients 116 operating on the computing device 110 and/or remote, storage clients 116 accessible via the network 115 and/or network interface 113. The storage clients 116 may include, but are not limited to: operating systems, file systems, database applications, server applications, kernel-level processes, user-level processes, applications, and the like.

A device driver may be communicatively coupled to one or more non-volatile memory devices 120. The one or more non-volatile memory devices 120 may include different types of non-volatile memory devices including, but not limited to: solid-state storage devices, semiconductor storage devices, SAN storage resources, or the like. The one or more non-volatile memory devices 120 may comprise one or more respective device controllers 126 and non-volatile memory media 122. A device driver may provide access to the one or more non-volatile memory devices 120 via a traditional block I/O interface 131. Additionally, a device driver may provide access to enhanced functionality through the SCM interface 132. The metadata 135 may be used to manage and/or track data operations performed through any of the Block I/O interface 131, SCM interface 132, cache interface 133, or other, related interfaces.

The cache interface 133 may expose cache-specific features accessible via a device driver for the non-volatile memory device 120. Also, in some embodiments, the SCM interface 132 presented to the storage clients 116 provides access to data transformations implemented by the one or more non-volatile memory devices 120 and/or the one or more device controllers 126.

A device driver may present a logical address space 134 to the storage clients 116 through one or more interfaces. As discussed above, the logical address space 134 may comprise a plurality of logical addresses, each corresponding to respective media locations the on one or more non-volatile memory devices 120. A device driver may maintain metadata 135 comprising any-to-any mappings between logical addresses and media locations, or the like.

A device driver may further comprise and/or be in communication with a non-volatile memory device interface 139 configured to transfer data, commands, and/or queries to the one or more non-volatile memory devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The non-volatile memory device interface 139 may communicate with the one or more non-volatile memory devices 120 using input-output control (IO-CTL) command(s), IO-CTL command extension(s), remote direct memory access, or the like.

The communication interface 113 may comprise one or more network interfaces configured to communicatively couple the computing device 110 and/or the device controller 126 to a network 115 and/or to one or more remote, network-accessible storage clients 116. The storage clients 116 may include local storage clients 116 operating on the computing device 110 and/or remote, storage clients 116 accessible via the network 115 and/or the network interface 113. The device controller 126 is part of and/or in communication with one or more non-volatile memory devices 120. Although FIG. 1 depicts a single non-volatile memory device 120, the disclosure is not limited in this regard and could be adapted to incorporate any number of non-volatile memory devices 120.

The non-volatile memory device 120 may comprise one or more elements 123 of non-volatile memory media 122, which may include but is not limited to: resistive random access memory (ReRAM), Memristor memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more elements 123 of non-volatile memory media 122, in certain embodiments, comprise storage class memory (SCM).

While legacy technologies such as NAND flash may be block and/or page addressable, storage class memory, in one embodiment, is byte addressable. In further embodiments, storage class memory may be faster and/or have a longer life (e.g., endurance) than NAND flash; may have a lower cost, use less power, and/or have a higher storage density than DRAM; or offer one or more other benefits or improvements when compared to other technologies. For example, storage class memory may comprise one or more non-volatile memory elements 123 of ReRAM, Memristor memory, programmable metallization cell memory, phase-change memory, nano RAM, nanocrystal wire-based memory, silicon-oxide based sub-10 nanometer process memory, graphene memory, SONOS memory, PMC memory, CBRAM, MRAM, and/or variations thereof.

While the non-volatile memory media 122 is referred to herein as “memory media,” in various embodiments, the non-volatile memory media 122 may more generally comprise one or more non-volatile recording media capable of recording data, which may be referred to as a non-volatile memory medium, a non-volatile storage medium, or the like. Further, the non-volatile memory device 120, in various embodiments, may comprise a non-volatile recording device, a non-volatile memory device, a non-volatile storage device, or the like. Similarly, a non-volatile memory element 123, in various embodiments, may comprise a non-volatile recording element, a non-volatile memory element, a non-volatile storage element, or the like.

The non-volatile memory media 122 may comprise one or more non-volatile memory elements 123, which may include, but are not limited to: chips, packages, planes, die, or the like. A device controller 126, external to the one or more non-volatile memory elements 123, may be configured to manage data operations on the non-volatile memory media 122, and may comprise one or more processors, programmable processors (e.g., FPGAs), ASICs, micro-controllers, or the like. In some embodiments, the device controller 126 is configured to store data on and/or read data from the non-volatile memory media 122, to transfer data to/from the non-volatile memory device 120, and so on.

The device controller 126 may be communicatively coupled to the non-volatile memory media 122 by way of a bus 127. The bus 127 may comprise an I/O bus for communicating data to/from the non-volatile memory elements 123. The bus 127 may further comprise a control bus for communicating addressing and other command and control information to the non-volatile memory elements 123. In some embodiments, the bus 127 may communicatively couple the non-volatile memory elements 123 to the device controller 126 in parallel. This parallel access may allow the non-volatile memory elements 123 to be managed as a group, forming a logical memory element 129. The logical memory element may be partitioned into respective logical memory units (e.g., logical pages) and/or logical memory divisions (e.g., logical blocks). The logical memory units may be formed by logically combining physical memory units of each of the non-volatile memory elements.

The device controller 126 may comprise and/or be in communication with a device driver executing on the computing device 110. A device driver may provide storage services to the storage clients 116 via one or more interfaces 131, 132, and/or 133. In some embodiments, a device driver provides a block-device I/O interface 131 through which storage clients 116 perform block-level I/O operations. Alternatively, or in addition, a device driver may provide a storage class memory (SCM) interface 132, which may provide other storage services to the storage clients 116. In some embodiments, the SCM interface 132 may comprise extensions to the block device interface 131 (e.g., storage clients 116 may access the SCM interface 132 through extensions or additions to the block device interface 131). Alternatively, or in addition, the SCM interface 132 may be provided as a separate API, service, and/or library. A device driver may be further configured to provide a cache interface 133 for caching data using the non-volatile memory system 102.

A device driver may further comprise a non-volatile memory device interface 139 that is configured to transfer data, commands, and/or queries to the device controller 126 over a bus 125, as described above.

FIG. 2 illustrates an embodiment of a non-volatile storage device 210 that may include one or more memory die or chips 212. A memory die or chip 212 may be a non-volatile memory element 123 as described above with regard to FIG. 1. The nonvolatile storage device 210 may be substantially similar to the nonvolatile memory device 120 described with reference to FIG. 1. Memory die 212, in some embodiments, includes an array (two-dimensional or three-dimensional) of memory cells 200, an on-die controller 220, and read/write circuits 230A/230B. In one embodiment, access to the memory array 200 by the various peripheral circuits is implemented in a symmetric fashion, on opposite sides of the array, so that the densities of access lines and circuitry on each side are reduced by half. The read/write circuits 230A/230B, in a further embodiment, include multiple sense blocks 250 which allow a page of memory cells to be read or programmed in parallel. In the depicted embodiment, peripheral circuits such as row decoders 240A/240B, column decoders 242A/242B, and read/write circuits 230A/230B are disposed at the edges of the memory array. In another embodiment, however, peripheral circuitry may be disposed above, below, and/or at the sides of a three-dimensional memory array 200.

The memory array 200, in various embodiments, is addressable by word lines via row decoders 240A/240B and by bit lines via column decoders 242A/242B. In some embodiments, a device controller 126 external to the memory die 212 is included in the same memory device 210 (e.g., a removable storage card or package) as the one or more memory die 212. Commands and data are transferred between the host and the device controller 126 via lines 232 and between the device controller 126 and the one or more memory die 212 via lines 234. One implementation can include multiple chips 212.

On-die controller 220, in one embodiment, cooperates with the read/write circuits 230A/230B to perform memory operations on the memory array 200. The on-die controller 220, in certain embodiments, includes a state machine 222, an on-chip address decoder 224, a power control circuit 226, and a write-time adjustment component 150, which may be substantially as described above with regard to FIG. 1. In various embodiments, a write-time adjustment component 150 may include or be embodied by an on-die controller 220, a state machine 222, a device controller 126, and/or a device driver.

The state machine 222, in one embodiment, provides chip-level control of memory operations. The on-chip address decoder 224 provides an address interface to convert between the address that is used by the host or a device controller 126 to the hardware address used by the decoders 240A, 240B, 242A, 242B. The power control circuit 226 controls the power and voltages supplied to the word lines and bit lines during memory operations. In one embodiment, power control circuit 226 includes one or more charge pumps that can create voltages larger than the supply voltage.

In one embodiment, one or any combination of on-die controller 220, power control circuit 226, on-chip address decoder 224, state machine 222, write-time adjustment component 150, decoder circuit 242A, decoder circuit 242B, decoder circuit 240A, decoder circuit 240B, read/write circuits 230A, read/write circuits 230B, and/or device controller 126 can be referred to as one or more managing circuits.

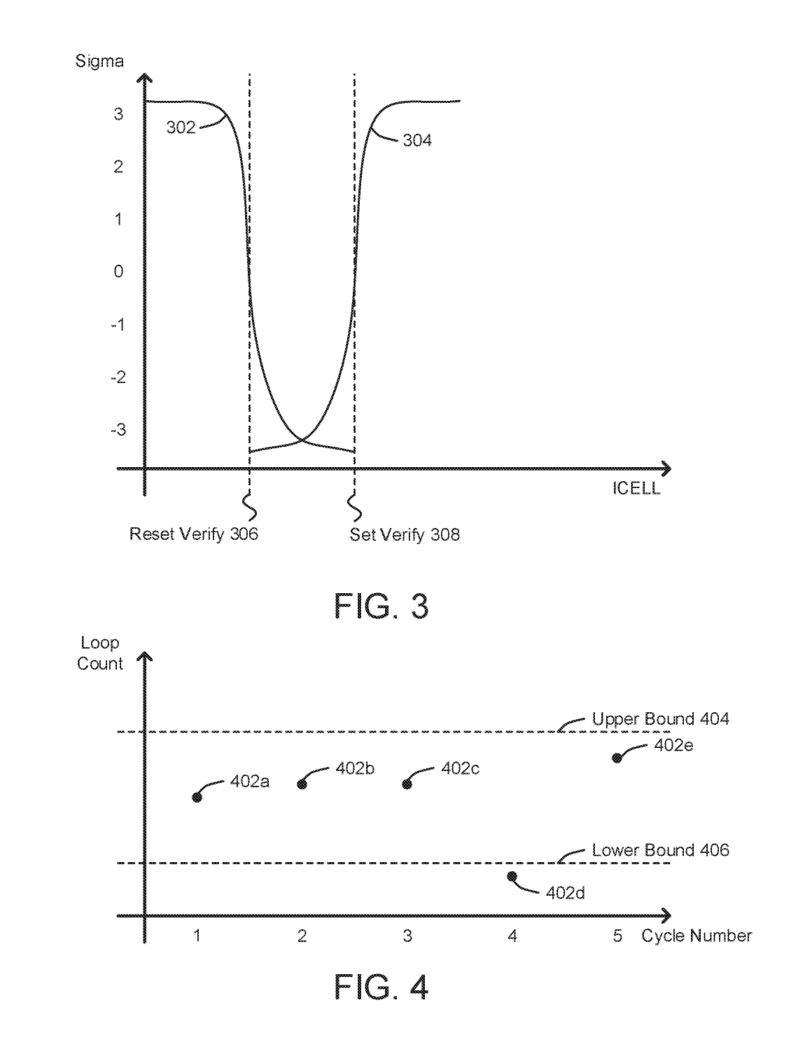

FIG. 3 is a graph illustrating cell currents for an array of non-volatile memory cells. As described above, a memory array 200 may include a plurality of non-volatile memory cells. In various embodiments, a memory cell may be any component with a physical property that is alterable to store data. For example, a memory cell for NAND memory may be a floating gate transistor, for which the threshold voltage (corresponding to an amount of stored charge on the floating gate) may be altered to store data. Similarly, a memory cell for phase change memory (PCM) may be a region of chalcogenide material, for which the electrical resistance (corresponding to crystallized or amorphous states for the chalcogenide material) may be altered to store data. In another embodiment, a memory cell for resistive random access memory (ReRAM) may be a dielectric material that forms conductive structures such as localized filaments or broader, substantially homogeneous conductive paths in response to an applied voltage, and the data-storing physical property may be the cell resistance. Various types of memory cells 318 for various types of non-volatile memory, such as ReRAM, PCM, MRAM, NAND, and the like, will be clear in view of this disclosure.

In FIG. 3, the memory array 200 is an array of resistive non-volatile memory cells, such as ReRAM cells, PCM cells, or the like, where the resistance of the cells is alterable to store data. The cell current ICELL in response to an applied bias voltage is depicted on the horizontal axis of the graph, where high currents correspond to low resistance cells, and low currents correspond to high resistance cells. In the depicted embodiment, the range of possible resistances (or, equivalently, the current range) is divided into two states, where the “set” state is a lower resistance (higher current) state, and the “reset” state is a higher-resistance (lower current state).

In various embodiments, writing data to a cell may involve performing one or more write loops, where a write loop includes a write sub-operation for changing the resistance or other data-storing physical property of the cell, and a verification sub-operation for checking the resistance or other data-storing physical property of the cell. In certain embodiments, a verification sub-operation may include comparing the resistance or other data-storing physical property of the cell to a verify threshold, to determine whether to perform another write loop. For example, in the depicted embodiment, write operations may include set or reset operations, where the set operation includes performing write loops until the cell current is above a set verify threshold 308, and the reset operation includes performing write loops until the cell current is below a reset verify threshold 306.

In the depicted embodiment, the reset verify threshold 306 and the set verify threshold 308 are at different cell current values. Because the resistance or other data-storing physical property of a cell may change unintentionally over time, providing a “window” between the reset verify threshold 306 and the set verify threshold 308 may allow some drift to occur without causing errors. For example, if a read operation determines whether a cell is in the “set” or “reset” state by comparing the cell current to a read threshold midway between the reset verify threshold 306 and the set verify threshold 308, then small resistance changes may occur over time without causing read errors.

The graph depicted in FIG. 3 includes a first curve 302 illustrating cell currents after a delay period for cells that have been reset, and a second curve 304 illustrating cell currents after a delay period for cells that have been set. The vertical axis depicts standard deviations (σ) from the mean. The curve 302 for the reset cells indicates that, some time after resetting the cells, the average cell current for the reset cells (σ=0) is approximately equal to the reset verify threshold 306. Furthermore, cell currents for most of the reset cells (−2<σ<2) are within a short distance of the reset verify threshold 306. However, for a small proportion of the cells, the resistance has drifted considerably. For example, cells with cell currents three or more standard distributions away from the mean may have currents that are considerably above or below the reset verify threshold 306. The curve 304 for the set cells is similar with regard to the set verify threshold 308: after a delay, most cell currents are close to the originally verified value at the set verify threshold 308, but a small proportion of cells have drifted considerably.

In the depicted embodiment, the curves 302, 304 cross, indicating that cell resistances for a small proportion of cells (σ<−3) have drifted to the point that some of the set cells have lower currents than some of the reset cells. Thus, a read operation may erroneously determine that a cell that was set by the write operation is now in the reset state, or that a cell that was reset by a write operation is now in the set state. In one embodiment, errors where the curves 302, 304 cross may be mitigated or eliminated by moving the curves 302, 304 further apart. For example, configuring the set verify threshold 308 to be further away from the reset verify threshold 306 may separate the curves 302, 304 so that they do not cross, or so that they cross for a much smaller proportion of the cells. However, widening the window between the reset verify threshold 306 and the set verify threshold 308 may increase wear on the cells, and reduce the endurance of a non-volatile memory element 123.

In certain embodiments, however, a write-time adjustment component 150 may identify one or more cells where data retention errors are likely during a write operation, and may modify the write operation (e.g., to widen the window between the reset verify threshold 306 and the set verify threshold 308) on the fly for the one or more identified cells. In certain embodiments, modifying a write operation on-the-fly for an identified cell may avoid excessive wear, because a low-wear, unmodified write operation may still be performed for other cells, or for subsequent writes to the identified cell.

Although FIG. 3 depicts cell currents for two-state resistive memory, similar data retention failures may occur for other types of memory, or for cells with more than two states. For example, threshold voltages that encode data for Flash memory cells may similarly drift past verify thresholds into other states. Similarly, a cell that stores two or three bits of data using four or eight states, respectively, may have multiple windows between states, where data retention failures may occur. Various types of memory for which a write-time adjustment component 150 may modify write operations on the fly will be clear in view ofthis disclosure.

FIG. 4 is a graph illustrating a write loop count 402 for multiple set operations for a non-volatile memory cell. As described above, a write operation (e.g., a set, reset, program, or erase operation) may include a sequence of write loops, where each write loop includes a write sub-operation for changing the resistance or other data-storing physical property of the cell, and a verification sub-operation for checking the resistance or other data-storing physical property of the cell, to determine whether to perform another write loop. In some embodiments, an unusual write loop count may be associated with data retention failure. For example, if a write operation takes an unusually high or unusually low number of write loops to write data to a particular cell, that cell may be more likely than other cells to drift into another state, causing a data retention failure.

In the graph depicted in FIG. 4, the horizontal axis depicts a set/reset cycle number, and the vertical axis depicts a loop count 402 for the set operation in each set/reset cycle. In various embodiments, a loop count 402 may similarly be maintained for reset operations, program operations, erase operations, or any other write operation. An upper bound 404 and a lower bound 406 are established for the loop count based on a prior characterization of the array 200 of cells. For example, a manufacturer may characterize the array 200 by repeatedly testing the array 200 (or a test array expected to have similar characteristics), and may measure statistics such as a mean, standard deviation, interquartile range, or the like, for loop counts 402. The upper bound 404 and the lower bound 406 may be established based on percentile levels, standard deviations from the mean, or the like.

In the depicted embodiment, the loop counts 402a, 402b, 402c, and 402e for the first, second, third, and fifth set operations, respectively, are above the lower bound 406 and below the upper bound 404. When the loop count 402 is within bounds for a cell, data retention failure for that cell may be unlikely, and a write-time adjustment component 150 may perform a write operation without modification. The unmodified write operation may have parameters that facilitate high endurance, such as a narrow window between the set verify threshold 308 and the reset verify threshold 306.

However, in the depicted embodiment, the loop count 402d for the fourth set operation is below the lower bound 406. When the loop count 402 is out of bounds for a cell (e.g., below the lower bound 406, or above the upper bound 404), data retention failure for that cell may be more likely, and a write-time adjustment component 150 may perform a write operation with modification for that cell. A modified write operation may have parameters that mitigate or prevent data retention failure, such as a wider window between the set verify threshold 308 and the reset verify threshold 306. Additionally, excessive wear based on the changed parameters may be avoided by the write-time adjustment component 150 returning to the original parameters to perform a subsequent write operation without modification. For example, in FIG. 4, the write-time adjustment component 150 may modify the set operation for cycle number 4, where the loop count 402d is out of bounds, but may perform an unmodified set operation in cycle number 5, where the loop count 402d is within bounds.

Although FIG. 4 depicts an out-of-bounds loop count 402d below the lower bound 406, a write-time adjustment component 150 may similarly modify a write operation for an out-of-bounds loop count 402 above the upper bound 404. Additionally, although FIG. 4 depicts loop counts 402 as an example of a characteristic associated with data retention failure, various other or further characteristics may similarly be associated with data retention failure, and may similarly be used by a write-time adjustment component 150 to determine when to perform modified write operations that mitigate or prevent data retention failure.

In certain embodiments, a write-time adjustment component 150 may track a write loop count 402 during a write operation. The write-time adjustment component 150 may determine that the write loop count 402 for a cell violates a lower bound 406 if the cell passes a verification sub-operation (e.g., verifies as having a cell current below the reset verify threshold 306 for a reset operation, or above the set verify threshold 308 for a set operation) without the write loop count 402 reaching (or exceeding) the lower bound 406. Conversely, the write-time adjustment component 150 may determine that the write loop count 402 for a cell violates an upper bound 404 if the write loop count 402 reaches (or exceeds) the upper bound 404 without the cell passing the verification sub-operation (e.g., while write loops for the write operation are still ongoing).

In a single-cell write operation (e.g., for bit-changeable non-volatile memory), a write loop count 402 for a write operation is equivalent to a write loop count for the cell where data is being written. In a multiple-cell write operation (e.g., for byte-changeable or page-changeable non-volatile memory) a write loop count 402 may be maintained for the write operation (so that the write loop count 402 is current for any cells that have not passed a verification sub-operation), or may be maintained separately for each cell.

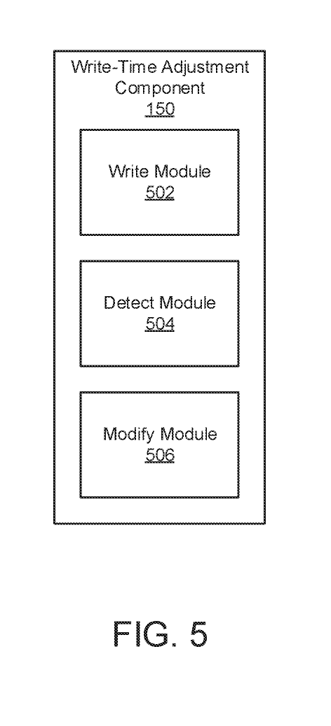

FIG. 5 depicts one embodiment of a write-time adjustment component 150. The write-time adjustment component 150 may be substantially similar to the write-time adjustment component 150 described above with regard to FIGS. 1-4. In general, as described above, the write-time adjustment component 150 is configured to perform a write operation, identify one or more cells during the write operation for which a cell characteristic is associated with data retention failure, and modify the write operation for the one or more identified cells. In the depicted embodiment, the write-time adjustment component 150 includes a write module 502, a detect module 504, and a modify module 506. In various embodiments, a controller, such as an on-die controller 220 for a single non-volatile memory element 123, a device controller 126 for a device comprising one or more non-volatile memory elements 123, a device driver comprising executable code stored on a computer-readable storage medium, or the like, may include the write module 502, the detect module 504, and the modify module 506.

The write module 502, in one embodiment, is configured to perform a write operation for at least one of the cells of the memory array 200. A write operation, in various embodiments, may include a set operation, a reset operation, a program operation, an erase operation, or any other operation that writes data to the cells. The write module 502 may perform a write operation in response to an external write request (e.g., from a client 116), or during internal grooming, garbage collection, wear leveling, or the like.

In one embodiment, the write module 502 may perform a single-cell write operation, which writes data to one cell of the array 200. For example, a single bit of data may be written or changed in a write operation for a single cell. Alternatively, a cell where the range of possible values for the resistance or other data-encoding physical property is divided into four, eight, or sixteen states (or the like) may store two, three, or four bits of data (respectively), and a write operation for a single cell may modify more than one bit.

In a certain embodiment, the write module 502 may perform a multiple-cell write operation, which writes data to multiple cells of the array 200. For example, the write module 502 may write a byte, a multiple-byte burst, a multiple-kilobyte page, or the like, to a group of cells during a multiple-cell write operation.

As described above, the write module 502 may perform a write operation by performing a sequence of one or more write loops, where each write loop includes a write sub-operation for changing the resistance or other data-storing physical property of one or more cells, and a verification sub-operation for checking the resistance or other data-storing physical property of the cell(s). The write module 502 may begin or initiate the write operation by starting or performing the first write loop, and may complete the write operation for a cell when the cell passes the verification sub-operation, indicating that the resistance or other data-storing physical property of the cell has reached a desired state, value, or range of values. In various embodiments, the write module 502 may include voltage and/or current sources, switching components for coupling write pulses to the cells, communication components for receiving data, registers or latches for storing the data prior to writing, logic hardware for continuing or stopping based on the verification sub-operation, registers or other memory for storing write operation parameters, and/or the like.

In certain embodiments, the nature of a write loop, and/or a number of write loops per write operation, may depend on the type of cells of the array 200. For example, in one embodiment, the array 200 may be a resistive random access memory (ReRAM) array, where the electrical resistance of a cell corresponds to the formation (or destruction) of conductive structures such as localized filaments or broader, substantially homogeneous conductive paths in a dielectric material. For a ReRAM array, a write sub-operation may include a current or voltage pulse, and a verify sub-operation may include checking the resistive state of the cell by applying a bias voltage pulse and measuring the cell current. Conductive structures may form (or break down) over the course of multiple write pulses, so a write module 502 for a ReRAM array may iteratively apply write pulses and verify pulses, and may increase the write voltage or duration for subsequent write pulses until a conductive structure is formed (or destroyed).

The number of write loops for writing data to a ReRAM array may depend on whether the write operation is a set operation that forms conductive structures, or a reset operation that breaks the conductive path). Additionally, the number of write loops may depend on the cell material. For example, a dielectric material where conductive filaments are formed at random locations may exhibit a large variance in the number of write loops applied during set or reset operations. By contrast, a dielectric material (or stack of layers) where substantially homogenous, non-filamentary conductive paths are formed may exhibit a smaller variance in the number of write loops applied during set or reset operations. In certain embodiments, the array 200 may be a barrier modulated cell (BMC) array, where a low resistance state for a cell is based on a non-filamentary conductive path through the cell. In some embodiments, cells of a BMC array may include a multiple-layer dielectric, such as at least one titanium oxide layer and at least one amorphous silicon layer. A non-filamentary or substantially homogenous conductive path may extend across a significant percentage of the cell area, such as 30% of the cell 50% of the cell, 80% of the cell, or the like. By contrast to a localized filament, which may form at a random location, a non-filamentary conductive path may form more predictably. Thus, in certain embodiments, a BMC array may have a lower variance in the number of write loops for a write operation than a filamentary ReRAM array, and a write operation that takes an unusually large or small number of write loops may suggest that data retention failure is likely.

In another embodiment, the array 200 may be a phase change memory (PCM) array, where the electrical resistance of a cell corresponds to the phase of the cell material (e.g., an amorphous, crystalline, or intermediate state). For a PCM array, a write sub-operation may be a current or voltage pulse configured to place the cell into the desired phase. For example, a current pulse may turn off quickly to facilitate quenching to an amorphous state, or may ramp down more slowly to facilitate crystallization. In certain embodiments, one such pulse may be sufficient to write data to a PCM cell by setting the resistance of the cell to a desired level or range. However, the write module 502 may still perform a verify sub-operation to check that the resistance of the cell has reached the desired level or range. If the cell does not pass the verify sub-operation, the write module 502 may repeat or modify the write pulse in a subsequent write loop. Thus, a write operation for a PCM array may complete in a single write loop, but may involve additional write loops.

The detect module 504, in one embodiment, is configured to identify, during a write operation performed by the write module 502, one or more cells for which a characteristic of the one or more identified cells is associated with data retention failure. In general, in various embodiments, using a detect module 504 to identify cells during a write operation where a cell characteristic is associated with data retention failure allows the write-time adjustment component 150 to adjust a write operation on the fly to prevent or mitigate data retention failures.

In various embodiments, a characteristic of a cell may refer to any property or attribute that may be measured or determined by the detect module 504. For example, in certain embodiments, a cell characteristic may be a write loop count, a cell current, a cell resistance, a cell threshold voltage, a cell state, or the like. In further embodiments, a characteristic of a cell may be “associated” with data retention failure, if the characteristic is statistically correlated to data retention failures, useful for predicting data retention failures, or the like. In certain embodiments, characteristics associated with data retention failures may depend on the type of array. For example, for a BMC array, a low write loop count and/or a high write loop count may be associated with a data retention failure. For a PCM array, relaxation of a cell after a delay period (e.g., during or between write loops) may include a change in the cell current or resistance, and may be useful to predict whether a data retention failure is likely. By contrast, however, simply failing a verification sub-operation and performing another write loop may be a normal part of the iterative sequence of write loops for a write operation, rather than a characteristic that predicts or is otherwise associated with data retention failure.

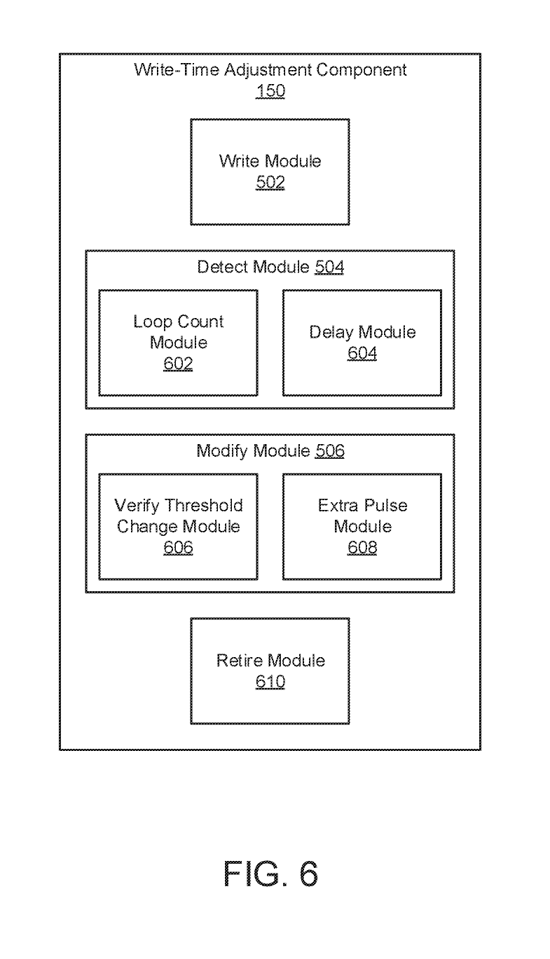

Various further characteristics associated with data retention failure for ReRAM or PCM arrays, or other characteristics associated with data retention failure for other types of arrays, will be clear in view of this disclosure. Certain characteristics including write loop counts and relaxation are described in further detail below with regard to the loop count module 602 and the delay module 604 of FIG. 6.

In certain embodiments, the detect module 504 may identify one or more cells during a write operation, for which a cell characteristic is associated with data retention failure, by monitoring the characteristic during the write operation. For example, the detect module 504 may maintain a write loop count, may monitor cell current or resistance during verify sub-operations, or the like. For a single-cell write operation, the detect module 504 may determine whether the measured characteristic is associated with a data retention failure (e.g., a loop count out of bounds) or not (e.g., a loop count within bounds). For a multiple-cell write operation, the detect module 504 may identify particular cells for which the measured characteristic is associated with a data retention failure. For example, in one embodiment, the detect module 504 may include a number of registers, latches, or other memory corresponding to the number of cells addressed by a write operation, and may use the registers, latches, or other memory to mark which cells it has identified. In further embodiments, the detect module 504 may include memory or a counter for tracking a write loop count, hardware for monitoring the cell characteristics or for communicating the monitoring hardware of write module 502 (e.g., for monitoring verify sub-operations), or the like.

The modify module 506, in one embodiment, is configured to modify the write operation for the one or more cells identified by the detect module 504. For example, in one embodiment, the modify module 506 may modify a write operation in response to the detect module 504 determining that a write loop count for a cell is out of bounds. In another embodiment, the modify module 506 may modify a write operation in response to the detect module 504 identifying cells for which another characteristic is associated with data retention failure.

In various embodiments, modifying a write operation may include changing the write operation in some way. For example, as described below with regard to the verify threshold change module 606 and the extra pulse module 608 of FIG. 6, modifying a write operation may include changing one or more verify thresholds, applying an extra write pulse to a cell after the cell passes a verification operation, or the like. In general, certain ways of modifying a write operation may prevent or mitigate data retention failures. Various other or further ways for a modify module 506 to prevent or mitigate data retention failures for various types of non-volatile memory arrays 200 will be clear in view of this disclosure. Modifying a write operation at write time, when characteristics associated with data failure are identified, may reduce wear compared to longer-term adjustments to write parameters, which may mitigate write errors but increase wear on the cells.

In one embodiment, the modify module 506 may modify the write operation by modifying a stored write operation parameter, and the write module 502 may continue the write operation with the modified parameter. In various embodiments, a write operation parameter may refer to any number, quantity, or other value that defines or affects conditions of a write operation. In certain embodiments, write operation parameters may be stored in registers, memory or the like. For example, the write module 502 may refer to a stored verify threshold (e.g. a set verify threshold 308, a reset verify threshold 306, or the like) to perform a verify sub-operation of a write loop. In further embodiments, the modify module 506 may access such a register (or other memory) to modify a stored write operation parameter.

In one embodiment, write parameters may be stored and used at a per-cell granularity. For example, in one embodiment, the modify module 506 may modify write parameters for individual cells of a multiple-cell write operation, and the write module 502 may continue the write operation with the modified parameters for the identified cells. In another embodiment, write parameters may be stored and used at another granularity. For example, in one embodiment, the write module 502 may complete a write operation with unmodified parameters for non-identified cells, the modify module 506 may modify the write operation parameter(s), and the write module 502 may continue a multi-cell write operation with the modified parameter(s) for just the identified cells.

In one embodiment, the modify module 506 may modify a write operation on the fly, for just the cell or cells identified by the detect module 504. For example, in one embodiment, the write module 502 may continue the write operation without modification for cells other than the one or more cells identified by the detect module 504. Performing an unmodified write operation for non-identified cells may reduce overall wear on the array 200, increasing endurance. In another embodiment, the write module 502 may begin a write operation without carrying over modifications of a previous write operation. For example, the modify module 506 may change modified write parameters back to their unmodified values after a modified write operation, so that the write module 502 begins a subsequent write operation with the unmodified parameters. Similarly, referring to FIG. 4, the modify module 506 may modify the write operation in cycle 4, where the loop count 402d is out of bounds, but the write module 502 may perform previous and/or subsequent write operations without modification in response to the detect module 504 determining that the write loop count is not out of bounds for those operations. Performing an unmodified write operation unless or until the detect module 504 identifies cells where a data retention failure is likely may reduce overall wear on the array 200, compared to making long-term modifications to write operation parameters.

FIG. 6 depicts another embodiment of a write-time adjustment component 150. The write-time adjustment component 150, in various embodiments, may be substantially similar to the write-time adjustment component 150 described above with regard to FIGS. 1-5. In the depicted embodiment, the write-time adjustment component 150 includes a write module 502, a detect module 504, and a modify module 506, which may be configured substantially as described above with regard to FIG. 5. The detect module 504, in the depicted embodiment, includes a loop count module 602 and a delay module 604. The modify module 506, in the depicted embodiment, includes a verify threshold change module 606 and an extra pulse module 608. Additionally, in the depicted embodiment, the write-time adjustment component 150 includes a retire module 610.

In one embodiment, a write loop count being out of bounds may be a characteristic associated with data retention failure, and the detect module 504 may use the loop count module 602 to identify cells for which the write loop count is out of bounds (e.g., the write loop count violates a bound or threshold). As depicted in FIG. 4, an upper bound 404 and a lower bound 406 may be established for a write loop count. In certain embodiments, loop count module 602 may maintain a loop count for a write operation performed by the write module 502. For example, the loop count module 602 may include a counter, a set of counters to track cells separately, or the like. Because a loop count for a write operation may begin at an initial value (e.g., zero or one) below a lower bound 406, the loop count module 602 may determine whether a loop count satisfies the lower bound 406 and/or the upper bound 404 with reference to verification sub-operations during a write loop.

In one embodiment, a bound such as a write loop count lower bound 406, or a write loop count upper bound 404 may be defined so that an acceptable value for the write loop count with relation to the bound “satisfies” the bound. For example, a write loop count lower bound 406 may be defined so that it is “satisfied” if the write loop count is greater than the lower bound 406, or so that it is “satisfied” if the write loop count is greater than or equal to the lower bound 406. Similarly, a write loop count upper bound 404 may be defined so that it is “satisfied” if the write loop count is less than the upper bound 404, or so that it is “satisfied” if the write loop count is less than or equal to the upper bound 404.

Similarly, a verification sub-operation may check the resistance or other data-encoding physical property of the cell, or a corresponding property such as the cell current, or may compare the resistance, other data-encoding physical property of the cell, or corresponding property to a verify threshold to determine whether the threshold is satisfied. A verify threshold may refer to any value used to verify whether a cell has reached a desired state. For example, in FIG. 3, the reset verify threshold 306 is used to verify whether a reset operation is complete, and the set verify threshold 308 is used to verify whether a set operation is complete. A cell that stores more than one bit using more than two states may include one or more additional thresholds between additional states. A cell may be referred to as passing the verification sub-operation if the verify threshold for the desired state in the write operation is satisfied (e.g., the set verify threshold 308 for a set operation, the reset verify threshold 306 for a reset operation, or the like)

In various embodiments, the loop count module 602 may determine whether a write loop count is out of bounds for a cell during a write operation. In one embodiment, the loop count module 602 may determine that the write loop count is out of bounds for a cell based on the cell passing a verification sub-operation without satisfying the write loop count lower bound 406. Thus, the loop count is “out of bounds” in relation to the lower bound 406 if it passes verification early, not simply when the initial value for the loop count is low. In another embodiment, or in another write operation, the loop count module 602 may determine that the write loop count is out of bounds for a cell based on the cell satisfying a write loop count upper bound 404 without passing the verification sub-operation.

In certain embodiments, the write loop count lower bound 406 and the write loop count upper bound 404 are predetermined based on a characterization of the array 200. A manufacturer or provider of a non-volatile memory element 123, a non-volatile memory device 120, or the like may characterize an array 200 by performing test writes on the array (or a similar array in another non-volatile memory element 123), recording loop counts for cells that experience data retention failures, or the like, to identify an upper bound 404 and a lower bound 406 that are associated with data retention failures.

In one embodiment, a relaxation violating a relaxation threshold may be a characteristic associated with data retention failure, and the detect module 504 may use the delay module 604 to identify cells for which the relaxation violated a relaxation threshold. In various embodiments, a relaxation for a cell may refer to a change in cell current, resistance, or another data-encoding physical property during a delay period. For example, a verification sub-operation performed one millisecond after a write sub-operation may verify that a cell current satisfies a verify threshold or is in the desired range, but repeating the verification operation after a 100 millisecond delay period may reveal that the cell current has drifted. In various embodiments, a relaxation threshold may be established such that a relaxation that violates the threshold predicts or is associated with data retention failures.

In various embodiments, the delay module 604 may wait a delay period, then determine whether relaxation that occurred during the delay period violated a relaxation threshold. The delay period, in various embodiments, may depend on the type of array but may be long enough for some relaxation to occur. For example, a delay period for ReRAM may be 20 milliseconds, 50 milliseconds, 100 milliseconds, 150 milliseconds, or the like. In various embodiments, the delay module 604 may include or communicate with a clock signal generator, or other timing circuit to measure the delay period.

The delay module 604 may measure the relaxation in various ways in various embodiments. For example, in one embodiment, the delay module 604 may determine a change or delta between cell currents before and after the delay period, and compare the delta to a retention threshold. In another embodiment, the delay module 604 may compare the cell current after the delay period to a retention threshold (similar to a verify threshold).

In one embodiment, the modify module 506 may modify a write operation for one or more cells identified by the detect module 504 by using the verify threshold change module 606 to change one or more verify thresholds for the identified cell(s). As described above, a verify threshold may refer to any value used to verify whether a cell has reached a desired state. In various embodiments, a verify threshold may include a set verify threshold 308, a reset verify threshold 306 and/or additional threshold(s) for further states (e.g., for multiple-bit cells). In certain embodiments, the verify threshold change module 606 may change a verify threshold by modifying a stored verify threshold referenced by the write module 502 for verification sub-operations, communicating a verify threshold offset to the write module 502, or the like.

In certain embodiments, the verify threshold change module 606 may increase a window between a set verify threshold 308 and a reset verify threshold 306. A window may refer to a measurement of a distance between any two verify thresholds that separate adjacent states. In general, increasing the size of a window between states reduces the likelihood of data retention failure because a larger window can compensate for larger drifts in the cell's stored value, but increases wear because a larger number of write pulses may be used for a write operation (so that a value for the cell current or other data-encoding property is not in the middle of the window). In certain embodiments, using a verify threshold change module 606 to increase a window on-the-fly for identified cells may prevent or mitigate data retention errors while reducing or avoiding negative endurance consequences.

In one embodiment, the modify module 506 may use the extra pulse module 608 to apply at least one write pulse to the one or more cells identified by the detect module 504, after the identified cell(s) pass a verification sub-operation. In certain embodiments, applying an extra write pulse after verification may change the cell current (or other data-encoding property) to be slightly further from the verify threshold, and may provide similar advantages to changing the verify threshold directly. Additionally, in certain embodiments, logic for an extra pulse module 608 to apply an extra write pulse after verification may be simpler than logic for a verify threshold change module 606 to change verify thresholds. In certain embodiments, the modify module 506 may use the extra pulse module 608 to apply an extra write pulse instead of, or in addition to, using the verify threshold change module 606 to change verify thresholds.

The retire module 610, in one embodiment, is configured to retire at least one cell based on a count of modified write operations satisfying a threshold. In certain embodiments, a threshold for the retire module 610 may be a maximum number of modified write operations for a cell, or for a region that includes the cell, such as a byte, a page, or a block. In certain embodiments, cells may exhibit characteristics associated with data retention failures occasionally, and an on-the-fly correction may prevent or mitigate data correction failures. However, a cell that is consistently or regularly corrected may be worn or otherwise physically failing, and may fail to retain data even with an on-the-fly correction to write operations. Accordingly, the retire module 610 may retire a cell, or a region that includes the cell, if a maximum number of corrections for the cell or the region is reached. Retiring a cell or a region may include marking the cell or the region as bad, excluding the cell or the region from further write operations, mapping a redundant cell or region to replace the retired cell or region, or the like. Various ways of using a retire module 610 to retire a cell or region will be clear in view of this disclosure.

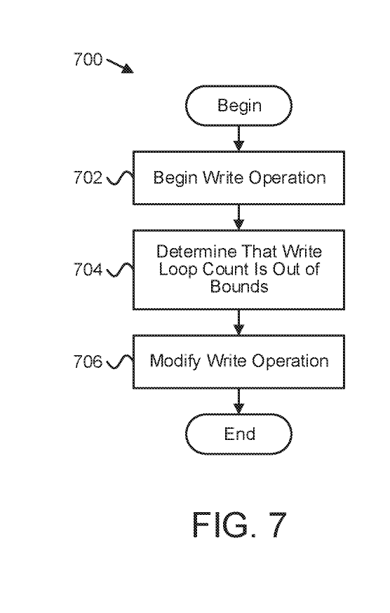

FIG. 7 depicts one embodiment of a method 700 for write-time prevention of data retention failures for non-volatile memory. The method 700 begins, and the write module 502 begins 702 a write operation for a cell of a non-volatile memory array 200. The detect module 504 determines 704, during the write operation, that a write loop count is out of bounds. The modify module 506 modifies 706 the write operation in response to the detect module 504 determining 704 that the write loop count is out of bounds, and the method 700 ends.

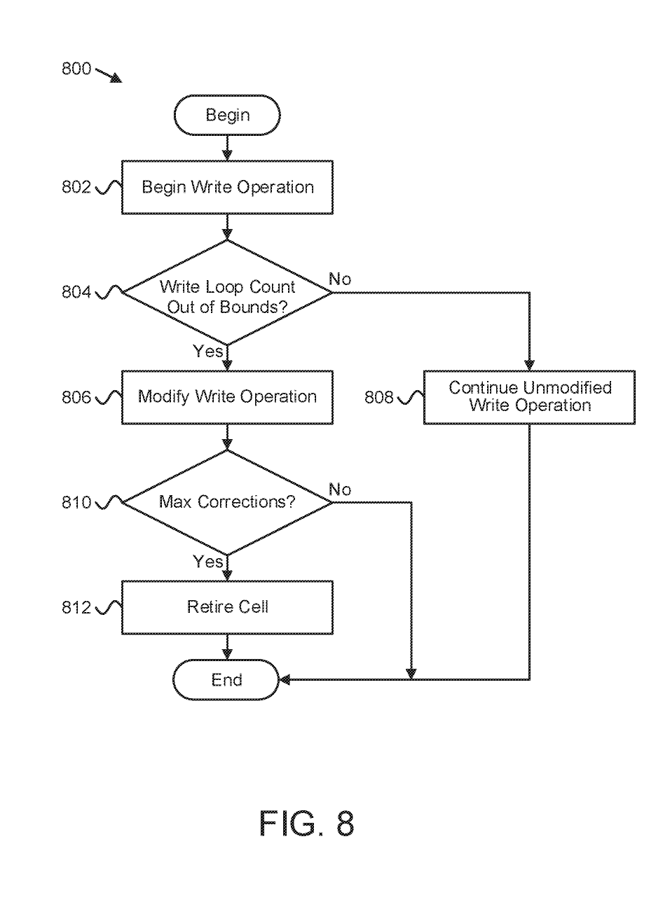

FIG. 8 depicts another embodiment of a method 800 for write-time prevention of data retention failures for non-volatile memory. The method 800 begins, and the write module 502 begins 802 a write operation for a cell of a non-volatile memory array 200. The detect module 504 determines 804, during the write operation, whether a write loop count is out of bounds. If the write loop count does not go out of bounds, the write module 502 continues 808 the unmodified write operation, and the method 800 ends. If the write loop count is out of bounds, the modify module 506 modifies 806 the write operation, and the retire module 610 determines 810 whether a count of modified write operations for the cell satisfies a threshold (e.g., is equal to or greater than a maximum number of corrections). If the count does not satisfy the threshold, the method 800 ends. If the count satisfies the threshold, the retire module 610 retires 812 the cell, and the method 800 ends.

In various embodiments, a means for performing a write operation for at least one cell of a non-volatile memory array may include a write module 502, a write-time adjustment component 150, a state machine 222, an on-die controller 220, a device controller 126, a device driver, other logic hardware and/or other executable code stored on a computer readable storage medium. Other embodiments may include similar or equivalent means for performing a write operation.

In various embodiments, a means for identifying, during the write operation, one or more cells for which a write loop count violates a threshold may include a detect module 504, a loop count module 602, a write-time adjustment component 150, a state machine 222, an on-die controller 220, a device controller 126, a device driver, other logic hardware and/or other executable code stored on a computer readable storage medium. Other embodiments may include similar or equivalent means for identifying cells during the write operation.

In various embodiments, a means for modifying one or more verify thresholds for the identified cells during the write operation may include a modify module 506, a verify threshold change module 606, a write-time adjustment component 150, a state machine 222, an on-die controller 220, a device controller 126, a device driver, other logic hardware and/or other executable code stored on a computer readable storage medium. Other embodiments may include similar or equivalent means for modifying one or more verify thresholds during the write operation.

In various embodiments, a means for applying at least one write pulse to the one or more identified cells after the one or more identified cells pass a verification sub-operation may include a modify module 506, an extra pulse module 608, a write-time adjustment component 150, a state machine 222, an on-die controller 220, a device controller 126, a device driver, other logic hardware and/or other executable code stored on a computer readable storage medium. Other embodiments may include similar or equivalent means for modifying one or more verify thresholds during the write operation.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. An apparatus comprising:
an array of non-volatile memory cells; and
a controller configured to:
perform a write operation for at least one of the cells;
identify, during the write operation, one or more cells for which a characteristic of the one or more identified cells is associated with data retention failure; and
modify the write operation for the one or more identified cells.

2. The apparatus of claim 1, wherein the controller is configured to continue the write operation without modification for cells other than the one or more identified cells.

3. The apparatus of claim 1, wherein the controller is configured to begin the write operation without carrying over modifications of a previous write operation.

4. The apparatus of claim 1, wherein the characteristic of the one or more identified cells is that a write loop count is out of bounds.

5. The apparatus of claim 4, wherein a write loop count is out of bounds for a cell based on one of:
the cell passing a verification sub-operation without satisfying a write loop count lower bound; and
the cell satisfying a write loop count upper bound without passing the verification sub-operation.

6. The apparatus of claim 5, wherein the write loop count lower bound and the write loop count upper bound are predetermined based on a characterization of the array.

7. The apparatus of claim 1, wherein the characteristic of the one or more identified cells is that relaxation for the one or more identified cells violates a relaxation threshold during a delay period observed by the controller during the write operation.

8. The apparatus of claim 1, wherein modifying the write operation comprises changing one or more verify thresholds for the one or more identified cells.

9. The apparatus of claim 1, wherein modifying the write operation comprises increasing a window between a set verify threshold and a reset verify threshold.

10. The apparatus of claim 1, wherein modifying the write operation comprises applying at least one write pulse to the one or more identified cells after the one or more identified cells pass a verification sub-operation.

11. The apparatus of claim 1, wherein modifying the write operation comprises modifying a stored write operation parameter and continuing the write operation with the modified parameter.

12. The apparatus of claim 1, wherein the controller is further configured to retire at least one cell based on a count of modified write operations satisfying a threshold.

13. The apparatus of claim 1, wherein the array of non-volatile memory cells comprises one of:
a barrier modulated cell (BMC) array, wherein a low resistance state for a cell is based on a non-filamentary conductive path through the cell; and
a phase change memory (PCM) array.

14. A method comprising:
beginning a write operation for a cell of a non-volatile memory array;
determining, during the write operation, whether a write loop count is out of bounds; and
modifying the write operation in response to determining that the write loop count is out of bounds.

15. The method of claim 14, further comprising:
determining, during a subsequent write operation for the cell, whether the write loop count is out of bounds; and
continuing the subsequent write operation without modification in response to determining that the write loop count is not out of bounds.

16. The method of claim 14, wherein determining that the write loop count is out of bounds is based on one of:
the cell passing a verification sub-operation without satisfying a write loop count lower bound; and
the cell satisfying a write loop count upper bound without passing the verification sub-operation.

17. The method of claim 14, wherein modifying the write operation comprises changing one or more verify thresholds for the cell.

18. The method of claim 14, further comprising:
maintaining a count of modified write operations for the cell; and
retiring the cell in response to the count satisfying a threshold.

19. An apparatus comprising:
means for performing a write operation for at least one cell of a non-volatile memory array;
means for identifying, during the write operation, one or more cells for which a write loop count violates a threshold; and
means for modifying one or more verify thresholds for the identified cells during the write operation.

20. The apparatus of claim 19, further comprising means for applying at least one write pulse to the one or more identified cells after the one or more identified cells pass a verification sub-operation.
